(19) United States
(12) Patent Application Publication
(10) Pub. No.: US 2007/0152347 A1
(43) Pub. Date: Jul. 5, 2007

(54) Face down type semiconductor device and manufacturing process of face down type semiconductor device

(75) Inventor: Eiji Hori, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC CORPORATION, Tokyo (JP)

(21) Appl. No.: 11/646,439

(22) Filed: Dec. 28, 2006

(30) Foreign Application Priority Data
Jan. 4, 2006 (JP) 289/2006

(51) Int. Cl. H01L 23/48

(52) U.S. Cl. 257/778

(57) ABSTRACT

A semiconductor device of the present invention includes a circuit board, a semiconductor element, a resin and a level display pad. On the circuit board substrate electrodes are provided. The semiconductor element is mounted on the circuit board via the substrate electrodes. The resin fills the gap between the semiconductor element and the circuit board. The level display pad is embedded in the resin and shows the distance from the surface of the circuit board.

### BACKGROUND OF THE INVENTION

The present invention relates to a face down type semiconductor device and a manufacturing process of the face down type semiconductor device, and more particularly to a face down type semiconductor device in which a semiconductor element can be easily replaced and a manufacturing process of such a face down type semiconductor device.

In a face down type semiconductor device, when some defect is found in a semiconductor element after mounting the semiconductor element on the circuit board, the replacement of the semiconductor element might be demanded. FIG. 4 is a flow diagram illustrating a method for replacing a semiconductor device in a conventional face down type semiconductor device. As shown in FIG. 4, a semiconductor element 1 is connected to a pad 21 on a circuit board 2 through a solder bump 3. Moreover, in order to improve the reliability of the connectivity of the solder bump 3, the gaps between the semiconductor element 1, the circuit board 2, and the solder bump 3 are filled with an underfill resin 4. Hereinafter, a method for replacing the semiconductor element 1 is described.

First of all, as shown in the step 1(a) of FIG. 4, in order to remove the semiconductor element 1, the face down type semiconductor device is heated up to temperature at which the solder bump 3 is melted and the semiconductor element 1 is taken out. Or, when the semiconductor element 1 does not need to be repaired, the semiconductor element 1 is scraped off by using a tool 7 such as an end mill, etc. as shown in the step 1(b) of FIG.4 , and the semiconductor element 1 is removed from the circuit board 2 (Japanese Unexamined Patent Publication No. 1999-186330).

Next, a large part of the underfill resin 4 remaining on the circuit board 2 is removed by using a tool 7 such as an end mill, etc. (step 2). Next, the underfill resin 4, which remains on the circuit board 2 because the underfill resin 4 cannot be completely removed in the step 2, is cleaned by using a cotton swab 8 containing an organic solvent, etc. (step 3). In order to make the cleaning in step 3 easy, it is preferable to control the thickness of the remaining underfill resin 4 to be about 20 μm or less in step 2.

After the cleaning is completed, a new semiconductor element 1 is connected through the solder bump 3 on the circuit board 2 (steps 4 to 5). The gaps between the semiconductor element 1, the circuit board 2, and the solder bump 3, are filled with the underfill resin 4, and then the filled underfill resin 4 is heated and cured by the heating(step 6). According to the above-mentioned processes, the semiconductor element 1 is replaced by a new semiconductor element 1.

### SUMMARY OF THE INVENTION

In the above-mentioned process for replacing the semiconductor element 1, it is difficult to determine the thickness of the underfill resin 4 remaining on the circuit board 2. This is because, as shown in FIG. 5, a worker removes the underfill resin 4 by using a tool 7 such as an end mill, etc. while making a visual observation. Therefore, a problem is that the work efficiency in the step of removing the underfill resin 4 becomes worse. Moreover, as shown in FIG. 5 (S3), since curvature or/and undulation of about 20 micro meter (μm) or less exist in the circuit board 2, another problem is that the surface of the circuit board 2 is scraped off together with the underfill resin 4.

An object of the present invention is to provide a face down type semiconductor device in which a semiconductor element can be easily replaced and a manufacturing process thereof.

According to one aspect of the present invention, a semiconductor device is provided which includes: a circuit board on which substrate electrodes. are provided, a semiconductor element mounted on the circuit board via the substrate electrodes, a resin which fills the gap between the semiconductor element and the circuit board and a level display pad which is embedded in the resin and shows the distance from the surface of the circuit board.

### BRIEF DESCRIPTION OF THE DRAWINGS

Other features and advantages of the invention will be made more apparent by the following detailed description and the accompanying drawings, wherein:

FIG. 1A is a cross-section diagram of a face down type semiconductor device in the first embodiment of the present invention;

FIG. 1B is a diagram illustrating a at the line connecting A-A of FIG. 1A as seen from the upper surface;

FIG. 2 is a flow diagram illustrating a manufacturing method of a face down type semiconductor device in the first embodiment of the present invention;

FIG. 3 is a flow diagram illustrating a method for replacing a semiconductor element 1 in a face down type semiconductor device in the first embodiment of the present invention;

FIG. 4 is a flow diagram illustrating a method for replacing a semiconductor element 1 in a face down type semiconductor device in the first embodiment of the present invention; and

FIG. 5 is a flow diagram illustrating a process for scraping the underfill resin of a face down type semiconductor device in the prior art.

In the drawings, the same reference numerals represent the same structural elements.

### DETAILED DESCRIPTION OF THE PREFERRED EMBODIMENTS

A first embodiment of the present invention will be described in detail below.

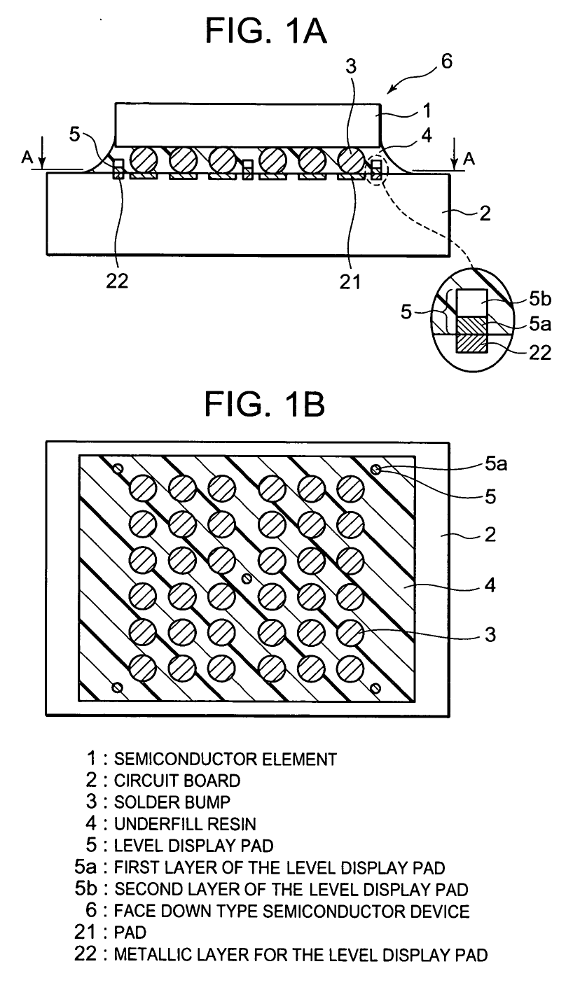

FIG. 1A is a cross-section diagram of a face down type semiconductor device in the first embodiment of the present invention and FIG. 1B is a diagram illustrating a at the line connecting A-A of FIG. 1A as seen from the upper surface. The semiconductor element 1 is mounted on the circuit board 2 by connecting the pad (circuit board electrode) 21 provided on the surface of the circuit board 2 to the solder bump 3 provided on the undersurface of the semiconductor element 1 (semiconductor chip) 1. Moreover, in order to improve the reliability of the connectivity of the solder bump 3, the gap between the semiconductor element 1 and the circuit board 2 is filled with the underfill resin 4 and sealed, thereby, embedding the solder bump 3 in the underfill resin 4. The level display pad 5 is arranged at a plurality of positions including the edge part surrounding a plurality of pads 21 on the circuit board 2 and the space between the adjacent pads 21. And the level display pad 5, For instance, has a cylindrical shape consisting of a double layer of the first layer 5a and the second layer 5b.

The level display pad 5 can be provided, for instance, by forming a metallic layer 22 simultaneously while forming the pad 21 on the surface of the circuit board 2; forming the first layer 5a of the level display pad on the metallic layer 22 by plating after forming the pad 21; and the second layer 5b is formed on the first layer 5a by a printing technique. The level display-pad 5 is also sealed by the underfill resin 4 together with the semiconductor element 1.

Next, a manufacturing method of a face down type semiconductor device 6 in the first embodiment of the present invention will be described below.

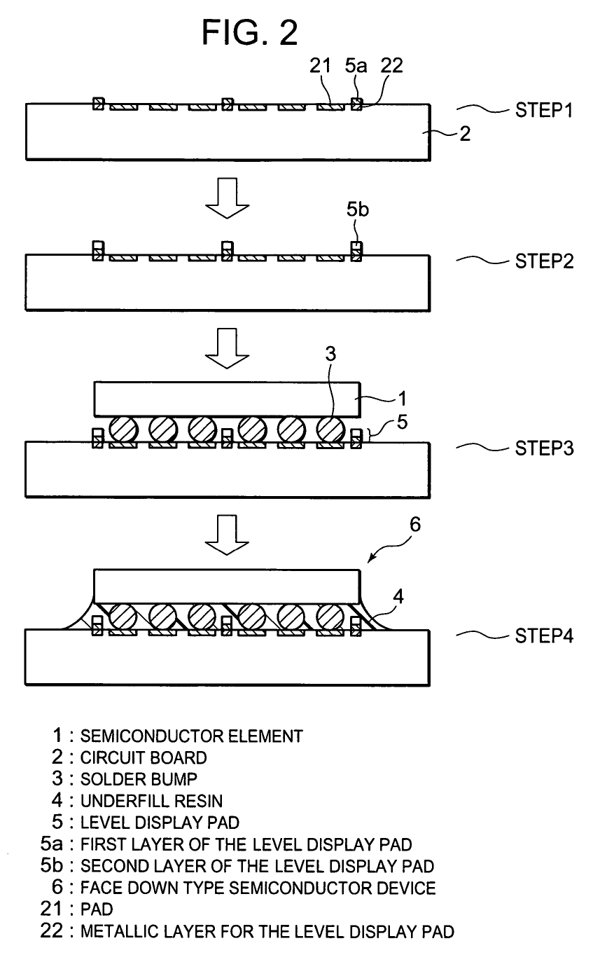

FIG. 2 is a flow diagram illustrating a manufacturing method of a face down type semiconductor device in the first embodiment of the present invention. First of all, when the pad 21 of the circuit board 2 is formed, the metallic layer 22 for the level display pad is formed simultaneously. The first layer 5a of the level display pad 5 is formed on the metallic layer 22 by plating, for instance, electroless nickel gold, etc. (step 1).

Next, on the first layer 5a of the level display pad 5, the second layer 5b, which is formed with material which is easily removed by using an organic solvent, is formed. For instance, the second layer 5b of the level display pad 5 can be formed by silk printing, etc (step 2).

Next, the solder bump 3 on the. undersurface of the semiconductor element 1 is overlapped with the pad 21 provided on the surface of the circuit board 2, and then they are heated up to a temperature at which the solder bump 3 is melted, and the semiconductor element 1 is mounted on the circuit board 2 (step 3). The gap between the semiconductor element 1 and the circuit board 2 is filled with the underfill resin 4 and the underfill resin 4 is cured by heating and the face down type semiconductor device 6 is completed(step 4).

Next, a manufacturing method and a method for replacing a semiconductor element 1 in a face down type semiconductor device in the first embodiment will be described below.

When the pad 21 of the circuit board 2 is formed, the metallic layer 22. for the level display pad 5 is formed simultaneously. The first layer 5a is formed on the metallic layer 22 by applying about a 20 μm thick nickel gold plating (FIG. 2, step 1). Next, the second layer 5b is formed by applying about a 50 μm thick white silk printing on the first layer 5a of the level display pad 5 (FIG. 2, step 2). The thicknesses of the first layer 5a and the second layer 5b are not limited to 20 μm and 50 μm, and they can be freely designed.

Then, the solder bump 3 on the. undersurface of the semiconductor element 1 is overlapped with the pad 21 provided on the surface of the circuit board 2, and then they are heated up to a temperature at which the solder bump 3 is melted, and the semiconductor element 1 is mounted on the circuit board 2 (FIG.2, step 3). The gap between the semiconductor element 1 and the circuit board 2 is filled with the underfill resin 4, and the underfill resin 4 is cured by heating, the face down type semiconductor device 6 is completed (FIG. 2, step 4).

A method for replacing the semiconductor element 1 of the face down type semiconductor device 6 obtained by the above-mentioned manufacturing method will be described below.

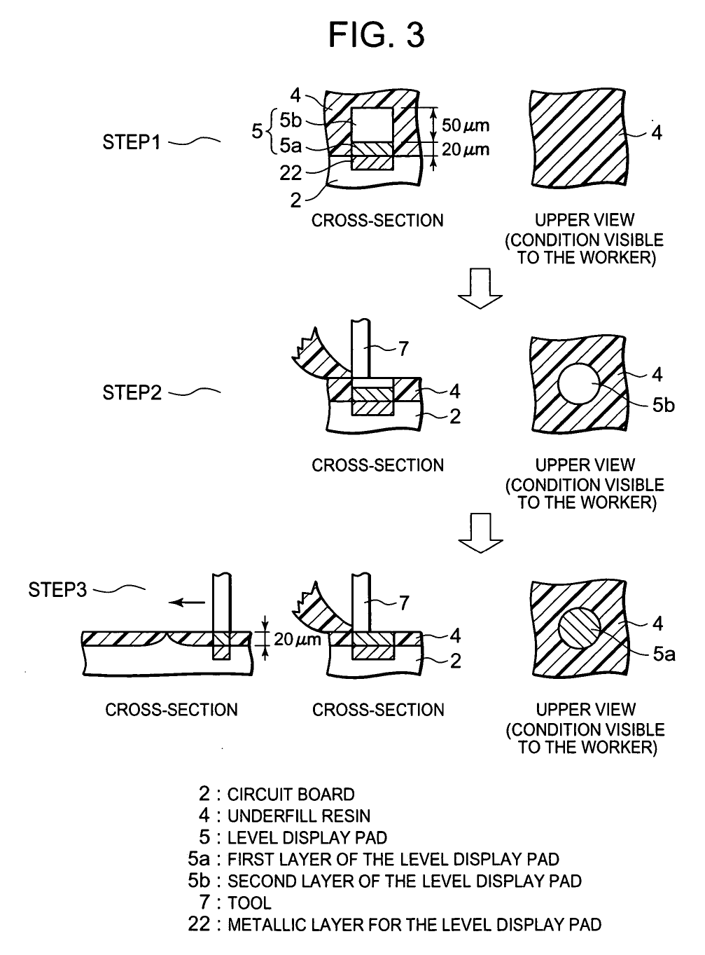

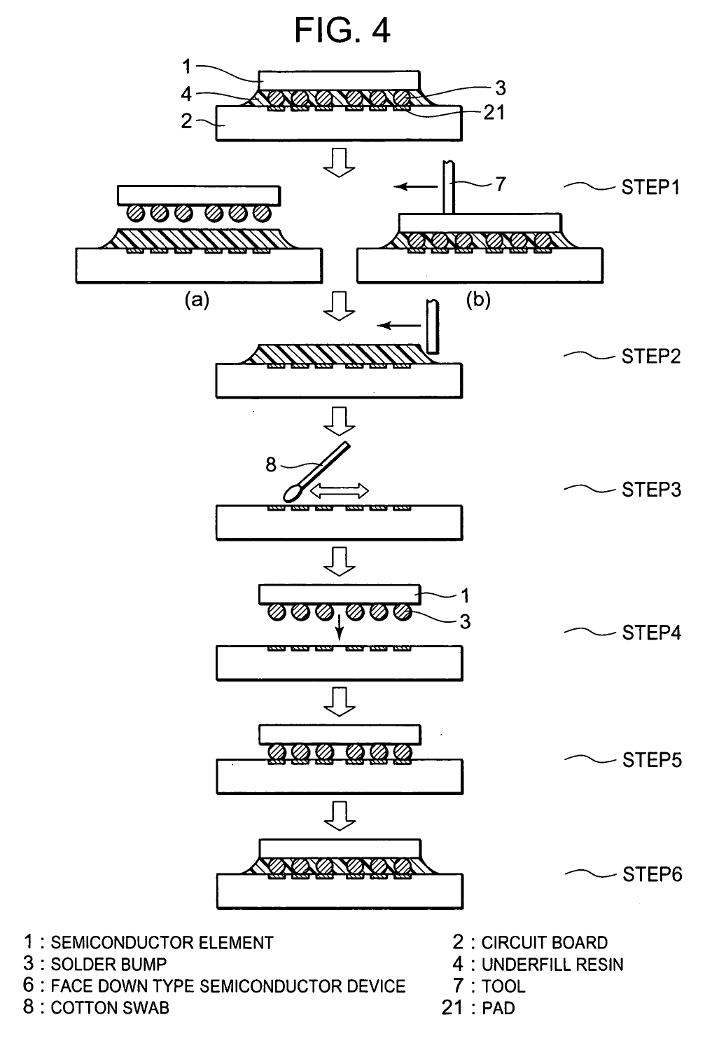

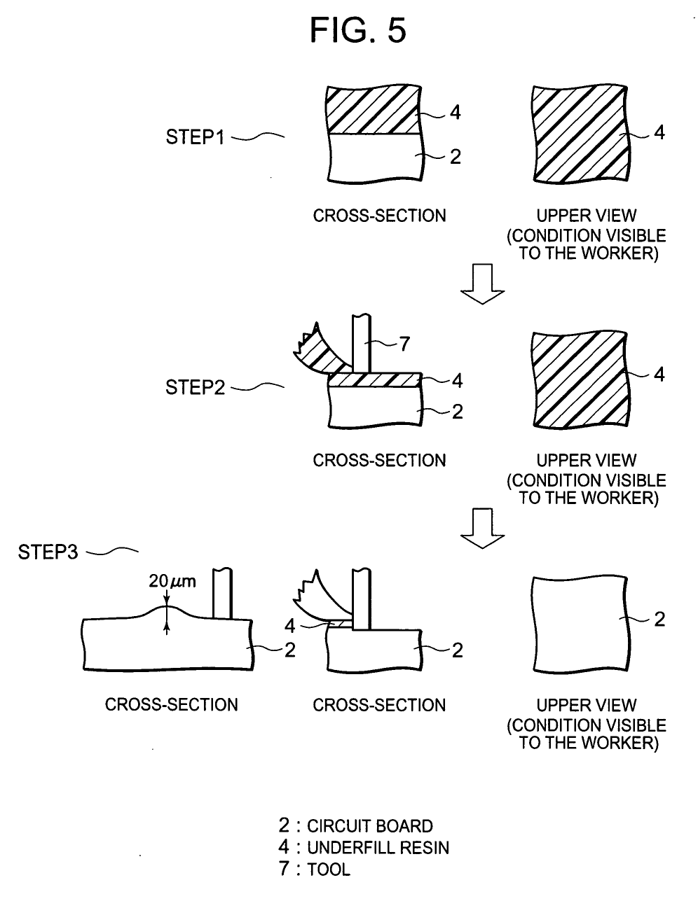

Referring to FIG. 3, first of all, the face down type semiconductor device 6 is heated up to a temperature at which the solder bump 3 is melted, and the semiconductor element 1 is taken out. Or, when the semiconductor element 1 does not need to be repaired, the semiconductor element 1 may be removed away from the circuit board 2 by scraping off the semiconductor element 1 using a tool 7. At this time, the level display pad 5 is sealed by the underfill resin 4 (step 1).

Next, using the tool 7 such as an end mill, etc. the underfill resin 4 remaining on the circuit board 2 is removed while visually confirming the level display pad 5. The second layer 5b is white and the first layer 5a is gold, so that the incision depth of the end mill can be set to be 50 μm in the step where a white color cannot be visually confirmed. Moreover, even if a white layer (the second layer 5b) appears, if the gold layer (the first layer 5a) cannot be visually confirmed, it can be easily judged that it is now in the step where the second layer 5b is being scraped, that is, where the underfill resin 4 of 20 μm or more remains.(step 2).

At the step where the gold layer (the first layer 5a) can be visually confirmed, the removing operation by using a tool 7 such as an end mill, etc. is stopped (step 3). Since the underfill resin 4 of about 20 μm remains, the surface of the circuit board 2 is never scraped down even if curvature and undulations of 20 μm or less exist in the circuit board 2.

Next, the underfill resin 4 which cannot be removed by using a tool 7 such as an endmill, etc. and remains on the circuit board 2 is cleaned by using a cotton swab containing an organic solvent.

The solder bump3 on the undersurface of the semiconductor element 1 is overlapped on the circuit board 2 where cleaning is complete, and then they are heated up to a temperature where the solder bump 3 is melted, and the semiconductor element 1 is mounted on the circuit board 2. The gap between the semiconductor element 1 and the circuit board 2 is filled with the underfill resin 4, and the underfill resin 4 is cured by heating. According to the above-mentioned processes, the semiconductor element 1 of the face down type semiconductor device 6 can be replaced by the new semiconductor element 1.

According to a face down type semiconductor device 6 and a manufacturing method of a circuit board 2, a worker can judge the remaining thickness of the underfill resin 4 by visually observing the level display pads 5 and can remove the underfill resin 4 efficiently by using a tool 7 such as an end mill, etc. without scraping the surface of the circuit board 2. Therefore, a replacement of a semiconductor element 1 of a face down type semiconductor device 6 becomes easy.

While this invention has been described in conjunction with the preferred embodiments described above, it will now be possible for those skilled in the art to put this invention. into practice in various other manners.

What is claimed is:

1. A semiconductor device comprising:
a circuit board on which substrate electrodes are provided;
a semiconductor element mounted on said circuit board via said substrate electrodes;
a resin which fills the gap between, said semiconductor element and said circuit board; and
a level display pad which is embedded in said resin and shows the distance from the surface of said circuit board.

2. A semiconductor device according to claim 1, further comprising a plurality of said level display pads which are arranged on an area which surrounds said substrate electrodes, and on an area between said substrate electrodes, on the surface of said circuit board.

3. A semiconductor device according to claim 1,
wherein said resin is resolved by an organic solvent.

4. A semiconductor device according to claim 3,
wherein a plurality of said level display pads are arranged on an area which surrounds said substrate electrodes, and on an area between said substrate electrodes, on the surface of said circuit board.

5. A semiconductor device according to claim 1, wherein said level display pad consists of a plurality of layers.

6. A semiconductor device according to claim 5,
wherein a plurality of said level display pads are arranged on an area which surrounds said substrate electrodes, and on an area between said substrate electrodes, on the surface of said circuit board.

7. A semiconductor device according to claim 5,
wherein said resin is resolved by an organic solvent.

8. A semiconductor device according to claim 7,
wherein a plurality of said level display pads are arranged on an area which surrounds said substrate electrodes, and on an area between said substrate electrodes, on the surface of said circuit board.

9. A semiconductor device according to claim 5,
wherein said level display pad includes a first layer which has a first color and a second layer which has second color.

10. A semiconductor device according to claim 9,
wherein a plurality of said level display pads are arranged on an area which surrounds said substrate electrodes, and on an area between said substrate electrodes, on the surface of said circuit board.

11. A semiconductor device according to claim 9, wherein said resin is resolved by an organic solvent.

12. A semiconductor device according to claim 11,
wherein a plurality of said level display pads are arranged on an area which surrounds said substrate electrodes, and on an area between said substrate electrodes, on the surface of said circuit board.

13. A semiconductor device according to claim 9,
wherein the distance from the surface on said circuit board to the border line between said first layer and said second layer shows the thickness of said resin which is made to remain when said semiconductor element is replaced.

14. A semiconductor device according to claim 13,
wherein a plurality of said level display pads are arranged on an area which surrounds said substrate electrodes, and on an area between said substrate electrodes, on the surface of said circuit board.

15. A semiconductor device according to claim 13, wherein said resin is resolved by an organic solvent.

16. A semiconductor device according to claim 15,
wherein a plurality of said level display pads are arranged on an area which surrounds said substrate electrodes, and on an area between said substrate electrodes, on the surface of said circuit board.

17. A manufacturing method of a semiconductor device comprising:
forming substrate electrodes on a circuit board;
mounting a semiconductor element on said circuit board via said substrate electrodes; and
filling the gap between said semiconductor element and said circuit board with a resin -in which a level display pad, which shows the distance from the surface of said circuit board, is embedded.

18. A manufacturing method of a semiconductor device comprising:
forming substrate electrodes on a circuit board;
forming a level display pad , which shows distance from the surface of said circuit board, on said circuit board;
mounting a semiconductor element on said circuit board via said substrate electrodes; and
filling the gap between said semiconductor element and said circuit board with a resin.

19. A manufacturing method of a semiconductor device according to claim 18,
wherein said step of forming said level display pad comprising:
forming a first layer on the surface of said circuit board; and
forming a second layer over said first layer.
